(19) United States
(12) Patent Application Publication
(10) Pub. No.: US 2022/0315801 A1
(43) Pub. Date: Oct. 6, 2022

(54) POLISHING COMPOSITION AND METHOD FOR SELECTIVELY REMOVING SILICON NITRIDE

(71) Applicant: FUJIMI INCORPORATED, Aichi (JP)

(72) Inventor: Jingzhi CHEN, Miaoli County (TW)

(21) Appl. No.: 17/702,941

(22) Filed: Mar. 24, 2022

(30) Foreign Application Priority Data
Mar. 30, 2021 (JP) 2021-057279

(51) Int. Cl. C09G 1/02; H01L 21/3105

(52) U.S. Cl. CPC C09G 1/02; H01L 21/31056

(57) ABSTRACT

The present invention provides a polishing composition and a method for selectively removing silicon nitride by use of the polishing composition. Such a polishing composition contains abrasive particles and at least one glucose derivative and has a pH of less than 3. According to the polishing composition of the present invention, the effect of efficiently and selectively removing silicon nitride can be achieved.

### TECHNICAL FIELD

The present invention is a polishing composition capable of selectively removing silicon nitride and a method for selectively removing silicon nitride using the polishing composition.

### BACKGROUND ART

In today's semiconductor industry, technologies for semiconductor manufacturing processes have been continually developed. In recent years, as more and more strict requirements have been made on the surface quality of wafers, a higher level of smoothness and flatness is required in polishing wafers. It has already been known that chemical mechanical polishing (hereinafter, referred to as “CMP”) can improve the surface quality of wafers.

For example, Patent Literature 1 discloses a composition for polishing a bare silicon wafer, containing abrasive particles, a basic compound, and two or more water-soluble polymers and having a pH of 8 to 12. The two or more water-soluble polymers have different affinities for silicon wafers and can act on each of the relatively inner and outer regions of the wafers during polishing. Consequently, the composition of Patent Literature 1 can achieve the purpose of controlling a wafer shape to a higher level while maintaining polishing speed.

Patent Literature 2 discloses a CMP composition containing cerium oxide (CeO₂) abrasive particles, glucoside, and water, and having a pH of 3 to 9. The composition of Patent Literature 2 has an effect of selectively removing silicon dioxide for polysilicon or silicon nitride.

Patent Literature 3 discloses a method for manufacturing a silicon wafer. A polishing slurry used in the manufacturing method contains abrasive particles, a water-soluble polymer, and a pH regulator (pH adjusting agent), and has a pH of 9 to 12. Patent Literature 3 also discloses a liquid composition capable of storing silicon wafers after polishing and before cleaning, during which period the abrasive particles become fixed to a wafer surface, and preventing them from being easily removed by the cleaning process. Alkyl polyglucosides may be added to the liquid composition.

Patent Literature 4 discloses a polishing composition containing abrasive particles, a water-soluble alkaline compound, a water-soluble polymer, an (alkyl)glucoside, and water. The composition of Patent Literature 4 can reduce a haze value of a wafer, improve the surface quality of the wafer, and impart moderate wettability to the wafer.

Patent Literature 5 discloses a metal polishing liquid containing abrasive particles, an organic acid, a heterocyclic compound, and an alkyl (poly)glucoside, and having a pH of 3 to 10. The polishing liquid has a quick polishing speed and high polishing accuracy and does not cause dishing even when used for high-purity materials, thus inhibiting corrosion in fine wiring as well as improving flatness.

### CITATION LIST

### Patent Literature

Patent Literature 1: International Publication No. WO 2018/124230
Patent Literature 2: International Publication No. WO 2013/035034
Patent Literature 3: Japanese Patent Laid-Open No. 2019-121795
Patent Literature 4: Japanese Patent Laid-Open No. 2018-206956
Patent Literature 5: Japanese Patent Laid-Open No. 2010-129941

### SUMMARY OF INVENTION

### Technical Problem

Incidentally, semiconductor wafers may contain various components such as polysilicon, silicon oxide, and silicon nitride. Compared to silicon nitride, polysilicon and silicon oxide (silicon dioxide) are softer and generally react with a polishing agent more easily. Although it is possible to improve the surface characteristic of an object to be polished such as the degree of flatness and haze and achieve the selective removal effect of silicon dioxide in Patent Literatures 1 to 5 above, the selective removal of silicon nitride has not yet been investigated.

In view of the above, an object of the present invention is to provide a polishing composition capable of selectively removing silicon nitride and a method for doing the same.

### Solution to Problem

As a result of earnest studies, the present inventors have found that the above object can be achieved by the following embodiments of the present invention (by way of example only, and not limited thereto).

A polishing composition according to the first embodiment of the present invention contains abrasive particles and at least one glucose derivative, and has a pH of less than 3.

The polishing composition according to the second embodiment of the present invention is the polishing composition of the first embodiment, containing at least two glucose derivatives.

The polishing composition according to the third embodiment of the present invention is the polishing composition of the first embodiment or the second embodiment, wherein the glucose derivative has an alkyl chain.

The polishing composition according to the fourth embodiment of the present invention is the polishing composition of any one of the first to third embodiments, wherein the glucose derivative has an oxyalkylene side chain.

The polishing composition according to the fifth embodiment of the present invention is the polishing composition of any one of the first to fourth embodiments, wherein the abrasive particles are colloidal silica.

The polishing composition according to the sixth embodiment of the present invention is the polishing composition of the fifth embodiment, wherein the colloidal silica is sulfonic acid-immobilized colloidal silica.

The polishing composition according to the seventh embodiment of the present invention is the polishing composition of any one of the first to sixth embodiments, further containing a chelating agent.

The polishing composition according to the eighth embodiment of the present invention is the polishing composition of the seventh embodiment, wherein the chelating agent is a phosphonate chelating agent.

The polishing composition according to the ninth embodiment of the present invention is the polishing composition of any one of the first to eighth embodiments, further containing a pH regulator.

A method for selectively removing silicon nitride according to the tenth embodiment of the present invention is a method involving using polishing composition any one of the first to ninth embodiments.

The method for surface treatment according to the eleventh embodiment of the present invention is a method for surface treatment including a step of performing surface treatment on an object to be treated using the polishing composition of any one of the first to ninth embodiments.

The method for surface treatment according to the twelfth embodiment of the present invention is the method for surface treatment of the eleventh embodiment, wherein the object to be treated includes at least silicon nitride.

The method for surface treatment according to the thirteenth embodiment of the present invention is the method for surface treatment of the eleventh embodiment or the twelfth embodiment, wherein the surface treatment is at least one selected from flattening treatment, selective removal treatment, and cleaning treatment.

The surface treatment apparatus according to the fourteenth embodiment of the present invention is a surface treatment apparatus including a mechanism for performing surface treatment on an object to be treated using the polishing composition of any one of the first to ninth embodiments.

The surface treatment apparatus according to the fifteenth embodiment of the present invention is the surface treatment apparatus of the fourteenth embodiment, wherein the object to be treated includes at least silicon nitride.

The surface treatment apparatus according to the sixteenth embodiment of the present invention is the surface treatment apparatus of the fourteenth embodiment or the fifteenth embodiment, wherein the surface treatment is at least one selected from flattening treatment, selective removal treatment, and cleaning treatment.

The method for manufacturing a semiconductor according to the seventeenth embodiment of the present invention is a method for manufacturing a semiconductor including a step of using the surface treatment apparatus of any one of the fourteenth to sixteenth embodiments.

The semiconductor manufacturing facility according to the eighteenth embodiment of the present invention is a semiconductor manufacturing facility including surface treatment apparatus of any one of the fourteenth to sixteenth embodiments.

Use according to the nineteenth embodiment of the present invention is use of the polishing composition of any one of the first to ninth embodiments for surface treatment.

The use according to the twentieth embodiment of the present invention is the use of the nineteenth embodiment, wherein the object to be treated in the surface treatment includes at least silicon nitride.

The use according to the twenty-first embodiment of the present invention is the use of the nineteenth embodiment or the twentieth embodiment, wherein the surface treatment is at least one selected from flattening treatment, selective removal treatment, and cleaning treatment.

### Effect of the Invention

According to the present invention, a polishing composition capable of selectively removing silicon nitride and a method for doing the same can be provided. In some embodiments, a polishing composition capable of selectively removing silicon nitride for polysilicon and a method for doing the same can be provided. Specifically, if polishing is performed using the polishing composition of these embodiments, silicon nitride can be effectively removed because it is possible to increase the removal rate of silicon nitride and decrease the removal rate of polysilicon. Note that since the removal rate of the polysilicon can be significantly lowered, it is also expected to have the effect of reducing damage to the polysilicon as much as possible.

### BRIEF DESCRIPTION OF THE DRAWING

FIG. 1 is a schematic diagram illustrating the principle of action of a chelating agent in a polishing composition of the seventh embodiment of the present invention.

### DESCRIPTION OF EMBODIMENTS

Hereinafter, embodiments of the present invention will be described in detail. In the present specification, “X to Y” indicating a range means “X or more and Y or less”. If there are multiple “X to Y” described, for example, “X1 to Y1, or X2 to Y2”, the disclosure of each numerical value as the upper limit, the disclosure of each numerical value as the lower limit, and the combination of those upper and lower limits are all disclosed (i.e., the lawful basis for the amendment). Specifically, amendments with X1 or more, amendments with Y2 or less, amendments with X1 or less, amendments with Y2 or more, amendments with X1 to X2, and amendments with X1 to Y2 etc. all must be considered legal. Unless otherwise specified, measurements of operation, physical properties, and the like are conducted under conditions of room temperature (20 to25° C.)/relative humidity (40 to 50% RH).

### [Polishing Composition]

The polishing composition of the present invention contains abrasive particles and at least one glucose derivative and has a pH of less than 3.

### [Abrasive Particle]

The material, shape, or the like of abrasive particles of the present invention may be appropriately selected according to the purpose and form of use of the polishing composition. The abrasive particles of the present invention may be at least one of inorganic particles, organic particles, or organic-inorganic composite particles. Examples of the inorganic particles include oxide particles such as silica particles, alumina particles, cerium oxide particles, chromium oxide particles, titanium dioxide particles, zirconia particles, magnesium oxide particles, manganese dioxide particles, zinc oxide particles, and iron oxide (e.g., Fe₃O₂) particles; nitride particles such as silicon nitride particles, and boron nitride particles; carbide particles such as silicon carbide particles and boron carbide particles; diamond particles; and carbonates such as calcium carbonate and barium carbonate. Examples of the organic particles include polymethyl methacrylate (PMMA) particles, polyacrylic acid particles, polymethacrylic acid particles, and polyacrylonitrile particles. The abrasive particles can be used singly or in the combination of two or more.

In one embodiment of the present invention, the abrasive particles preferably include silica particles and more preferably include colloidal silica (colloidal silica particles). If the abrasive particles include silica particles, the mass percentage of the silica particles in the total abrasive particles is 80% by mass or more, 90% by mass or more, 95% by mass or more, 96% by mass or more, 97% by mass or more, 98% by mass or more, 99% by mass or more, or 100% by mass.

The colloidal silica that can be used in the present invention can be any one that is commonly used in the field of CMP technology. Examples thereof include colloidal silica prepared by ion exchange of water glass (sodium silicate) as the raw material and alkoxide-based colloidal silica. The alkoxide-based colloidal silica refers to colloidal silica manufactured by hydrolysis and condensation reactions of an alkoxysilane. The colloidal silica can be used singly or in the combination of two or more. Colloidal silica in Examples is prepared by an alkoxide method.

General colloidal silica has a zeta potential value of nearly zero under acidic conditions and therefore tends to cause agglomeration without electrical repulsion among silica particles under acidic conditions. In contrast, surface modification of colloidal silica so that the colloidal silica has a relatively large positive or negative zeta potential value even under acidic conditions allows the colloidal silica to be strongly repelled with each other and well dispersed even under the acidic conditions, resulting in improved storage stability of the polishing composition.

As surface-modified colloidal silica, colloidal silica of which surface is immobilized with an organic acid can be used. Immobilization of an organic acid to a surface of colloidal silica is performed by chemical bonding of a functional group of the organic acid to the surface of the colloidal silica. Only by making the colloidal silica and the organic acid coexist, the organic acid is not immobilized to the colloidal silica. Specific examples of the organic acid include sulfonic acid, carboxylic acid, sulfinic acid, and phosphonic acid.

Sulfonic acid can be immobilized to colloidal silica, for example, by a method described in “Sulfonic acid-functionalized silica through quantitative oxidation of thiol groups”, Chem. Commun. 246-247 (2003). Specifically, colloidal silica of which surface is immobilized with sulfonic acid can be obtained by coupling a silane coupling agent having a thiol group such as 3-mercaptopropyl trimethoxysilane to colloidal silica and then oxidizing the thiol group with hydrogen peroxide. The colloidal silica used in the following Examples can be manufactured using the above method. Alternatively, the carboxylic acid can be immobilized to colloidal silica, for example, by a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, colloidal silica of which surface is immobilized with carboxylic acid can be obtained by coupling a silane coupling agent containing a photoreactive 2-nitrobenzyl ester to colloidal silica and then irradiating the resulting product with light.

As the colloidal silica of which surface is immobilized with the organic acid, sulfonic acid-immobilized colloidal silica is preferable.

The silica constituting the silica particles has a true specific gravity of preferably 1.5 or more, more preferably 1.6 or more, and still more preferably 1.7 or more. With increasing the true specific gravity of the silica, the polishing rate tends to increase. From such as standpoint, silica particles having a true specific gravity of 2.0 or more (e.g., 2.1 or more) are particularly preferable. The upper limit of the true specific gravity of the silica is not particularly limited, and it is typically 2.3 or less, for example, 2.2 or less. As the true specific gravity of the silica, the value measured by a liquid displacement method using ethanol as the displacing liquid can be employed. Note that the true specific gravity is a value that may vary depending on methods for manufacturing the silica. The silica used in Examples has a true specific gravity of 1.88.

The average primary particle size of the abrasive particles is not particularly limited and can be appropriately selected from a range of approximately 5 nm to 100 nm. From the standpoint of improvement in bump-cancellation abilities, the average primary particle size is preferably 5 nm or more, more preferably 7 nm or more, and still more preferably 10 nm or more, and is in some embodiments, 15 nm or more, 20 nm or more, 25 nm or more, 30 nm or more, or 31 nm. From the standpoint of preventing an occurrence of scratches, the average primary particle size is usually advantageous to be 200 nm or less, preferably 150 nm or less, and more preferably 100 nm or less, and is in some embodiments, 90 nm or less, 80 nm or less, 70 nm or less, 60 nm or less, 50 nm or less, 45 nm or less, 40 nm or less, or 39 nm or less. For the average primary particle size of the abrasive particles, a specific surface area of the abrasive particles is first measured by a BET method, and then the value of the average primary particle size of the abrasive particles can be calculated based on the measured specific surface area. In Examples, the calculation is also made in such a manner.

The abrasive particles have an average secondary particle size of preferably 25 nm or more, more preferably 30 nm or more, and still more preferably 35 nm or more, and in some embodiments, 40 nm or more, 45 nm or more, 50 nm or more, 55 nm or more, 60 nm or more, 65 nm or more, or 66 nm or more. As the average secondary particle size of the abrasive particles becomes larger, the polishing speed for an object to be polished (e.g., object to be polished containing silicon or silicon germanium material) increases.

The abrasive particles have an average secondary particle size of preferably 300 nm or less, more preferably 260 nm or less, and still more preferably 220 nm or less, and in some embodiments, 200 nm or less, 180 nm or less, 160 nm or less, 140 nm or less, 120 nm or less, 100 nm or less, 90 nm or less, 80 nm or less, 75 nm or less, or 74 nm or less. As the average secondary particle size of the abrasive particles becomes smaller, a polished surface with fewer scratches can be easily obtained when an object to be polished is polished using the polishing composition. The value of average secondary particle size of the abrasive particles can be measured by a suitable method, for example, a laser scattering method. In Examples, the calculation is also made in such a manner.

The shape (outer shape) of the abrasive particles may be a globular shape or a non-globular shape. Specific examples of non-globular shapes of the particles include a peanut shape, that is, a peanut shell shape, a cocoon shape, a shape with protrusions such as a kompeito shape, and a rugby ball shape. In Examples of this application, the cocoon shape is used. The use of abrasive particles with such a shape has the effect of improving the polishing speed.

The average aspect ratio of the abrasive particles is not particularly limited. The average aspect ratio of the abrasive particles is theoretically 1.0 or more and can be 1.05 or more or 1.1 or more. With increasing the average aspect ratio, bump-cancellation abilities tend to improve in general. From the standpoint of scratch reduction and improvement in polishing stability, the abrasive particles have an average aspect ratio of preferably 3.0 or less and more preferably 2.0 or less. In some aspects, the abrasive particles may have an average aspect ratio of, for example, 1.5 or less, 1.4 or less, or 1.3 or less. Note that the abrasive particles used in Examples have an aspect ratio of 1.24.

In some embodiments, abrasive particles can be employed in which the volume percentage of particles having an aspect ratio of 1.2 or more is 50% or more. The volume percentage can also be 60% or more. If the value of the volume percentage is 50% or more, or even more specifically, 60% or more, it is possible to further improve bump-cancellation abilities by the mechanical action of the abrasive particles for the reason that particles having a size and an aspect ratio particularly effective for bump cancellation are contained in the abrasive particles in relatively large quantities.

The abrasive particle content is not particularly limited and can be set appropriately according to the purpose. The abrasive particle content relative to the total mass of the polishing composition may be, for example, 0.01% by mass or more, 0.05% by mass or more, or 0.1% by mass or more. With increasing the abrasive particle content, bump-cancellation abilities tend to improve in general. In some embodiments, the abrasive particle content may be 0.2% by mass or more, 0.3% by mass or more, 0.4% by mass or more, or 0.45% by mass or more. From the standpoint of preventing scratches and saving the amount of abrasive particles used, in some embodiments, the abrasive particle content may be, for example, 10% by mass or less, 5% by mass or less, 3% by mass or less, 2% by mass or less, 1.5% by mass or less, 1.0% by mass or less, 0.9% by mass or less, 0.8% by mass or less, 0.7% by mass or less, or 0.6% by mass or less. These contents can be preferably applied, for example, to the content in a polishing liquid (working slurry) supplied to an object to be polished.

### [Glucose Derivative]

The polishing composition of the present invention contains at least one glucose derivative and preferably at least two glucose derivatives. If one glucose derivative is contained in the polishing composition of the present invention, it is referred to as the first glucose derivative. If two glucose derivatives are contained in the polishing composition of the present invention, one is referred to as the first glucose derivative while the other is referred to as the second glucose derivative. If three or more glucose derivatives are contained in the polishing composition of the present invention, they are referred to as the first glucose derivative, the second glucose derivative, the third glucose derivative, the fourth glucose derivative, and so on. In some embodiments, the types of glucose derivatives are, for example, four or less, three or less, or two.

Surprisingly, when a glucose derivative is used in the polishing composition of the present invention, the polishing composition shows an inhibitory effect on polishing of components other than silicon nitride (e.g., polysilicon), and as a result, it is possible to selectively remove silicon nitride. In some embodiments, when two or more glucose derivatives are used in the polishing composition, the removal rate of silicon nitride can be improved in addition to inhibiting the polishing of components other than silicon nitride. It is speculated (though not limited to theory) that at least part of the reason for this is that the glucose derivatives have a relatively high affinity with components other than silicon nitride in the object to be treated, and thus a thin film is formed on its top during polishing, which can inhibit the polishing of the components.

The glucose derivative used in the present invention may be any known glucose derivative and is not particularly limited, but does not include glucose itself. Examples thereof include polysaccharides such as cellulose and starch, glucosides, and oxyalkylene derivatives of methyl glucoside disclosed in U.S. Patent No. 2018/305580, which is incorporated into the present invention by reference in its entirety. In some embodiments, the glucose derivative used is a product obtained by chemical reactions (e.g., esterification or etherification) of hydroxy groups in glucose. The glucose derivative has an alkyl chain or/and an oxyalkylene side chain. The oxyalkylene may be, for example, derived from oxyethylene and/or oxypropylene, but is not limited thereto.

According to some embodiments, the glucose derivative having an alkyl chain is preferably a glucose derivative having an alkyl chain of 1 to 20 carbon atoms (2 to 19 carbon atoms, 3 to 18 carbon atoms, 4 to 17 carbon atoms, 5 to 16 carbon atoms, 6 to 15 carbon atoms, 7 to 14 carbon atoms, 8 to 13 carbon atoms, 9 to 12 carbon atoms, or 10 or 11 carbon atoms) or a mixture thereof. Examples thereof include lauryl glucoside, decylglucoside, hexylglucoside, coco glucoside, caprylyl/myristyl glucoside, caprylyl/capryl glucoside, lauryl/myristyl glucoside, C9-11 alkyl glucoside mixtures, C10-16 alkyl glucoside mixtures, and C8-16 alkyl glucoside mixtures.

According to some embodiments, the glucose derivative used is a glucose derivative having an alkyl chain represented by the following formula (1).

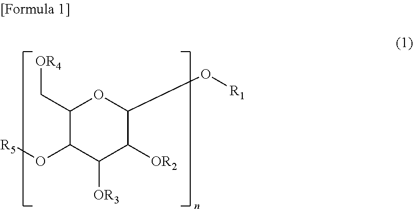

In formula (1), R₁ is a C1 to C20 alkyl group, preferably a C4 to C20 alkyl group, and more preferably a C6 to C16 alkyl group, and is in some embodiments, a C2 to C19 alkyl group, a C3 to C18 alkyl group, a C4 to C17 alkyl group, a C5 to C16 alkyl group, a C6 to C15 alkyl group, a C7 to C14 alkyl group, a C8 to C13 alkyl group, a C9 to C12 alkyl group, or a C10 to 11 alkyl group. According to some embodiments, the glucose derivative having an alkyl chain represented by formula (1) is in the form of a mixture having a plurality of alkyl groups shown in R₁. The alkyl groups may be linear or branched.

According to some embodiments, the glucose derivative having an alkyl chain represented by formula (1) is in the form of a mixture of glucose derivatives where R₁ is a C3 to 18 alkyl group, R₁ is a C4 to C17 alkyl group, R₁ is a C5 to C16 alkyl group, R₁ is a C6 to C15 alkyl group, R₁ is a C7 to C15 alkyl group, R₁ is a C8 to C15 alkyl group, or R₁ is a C9 to C15 alkyl group. Here, for example, the form of a mixture of glucose derivatives where R₁ is a C9 to C15 alkyl group refers to a mixture of glucose derivatives having an alkyl chain represented by formula (1), wherein the mixture contains at least two compounds selected from the group consisting of a glucose derivative where R₁ is a C9 alkyl group (R₂ to R₅, n is arbitrary) in formula (1), a glucose derivative where R₁ is a C10 alkyl group (R₂ to R₅, n is arbitrary) in formula (1), a glucose derivative where R₁ is a C11 alkyl group (R₂ to R₅, n is arbitrary) in formula (1), a glucose derivative where R₁ is a C12 alkyl group (R₂ to R₅, n is arbitrary) in formula (1), a glucose derivative where R₁ is a C13 alkyl group (R₂ to R₅, n is arbitrary) in formula (1), a glucose derivative where R₁ is a C14 alkyl group (R₂ to R₅, n is arbitrary) in formula (1), and a glucose derivative where R₁ is a C15 alkyl group (R₂ to R₅, n is arbitrary) in formula (1), at least two of which are endpoint compounds. That is, a mixture of glucose derivatives where R₁ is a C9 to C15 alkyl group includes a glucose derivative where R₁ is a C9 alkyl group (R₂ to R₅, n is arbitrary) in formula (1) as an endpoint compound and a glucose derivative where R₁ is a C15 alkyl group (R₂ to R₅, n is arbitrary) in formula (1) as an endpoint compound. In the present specification, it is understood in the same way.

According to some embodiments, the glucose derivative having an alkyl chain represented by formula (1) is in the form of a mixture where R₁ is a C3 to 13 alkyl group, R₁ is a C4 to C12 alkyl group, R₁ is a C5 to C11 alkyl group, R₁ is a C6 to C11 alkyl group, R₁ is a C7 to C11 alkyl group, R₁ is a C8 to C11 alkyl group, or R₁ is a C9 to C11 alkyl group. In some embodiments, the glucose derivative in the form of a mixture is substantially free of a glucose derivative where R₁ has a C12- or higher-, C13- or higher-, C14- or higher-, or C15- or higher-alkyl group. Here, “substantially free of” means that a component to be excluded is not contained unless it is inevitably introduced, for example, due to raw material origin or the like. The term “substantially free of” as used herein is to be interpreted in such a manner.

According to some embodiments, the glucose derivative having an alkyl chain represented by formula (1) is in the form of a mixture where R₁ is a C8 to 18 alkyl group, R₁ is a C9 to C17 alkyl group, R₁ is a C10 to C16 alkyl group, R₁ is a C11 to C15 alkyl group, R₁ is a C11 to C14 alkyl group, or R₁ is a C12 to C14 alkyl group. In some embodiments, the glucose derivative in the form of a mixture is substantially free of a glucose derivative where R₁ has a C12- or lower-, C11- or lower-, C10- or lower-, C9- or lower- or C8- or lower-alkyl group.

In formula (1), R₂, R₃, R₄, and R₅ are each independently a hydrogen atom or a C1 to C4 alkyl group, preferably a hydrogen atom or a methyl group, and more preferably a hydrogen atom. According to some embodiments, in formula (1), R₂, R₃, R₄, and R₅ are each independently a C1 to C3 alkyl group or a C1 or C2 alkyl group.

In formula (1), n is, for example, 1 to 5.

According to some embodiments, the glucose derivative having an oxyalkylene side chain is preferably a glucose derivative having an oxyethylene side chain, an oxypropylene side chain, or both side chains. Examples thereof include a glucose derivative having an oxyethylene side chain, a glucose derivative having an oxypropylene side chain, or a glucose derivative having oxyethylene/oxypropylene side chains. For the glucose derivative having an oxyethylene/oxypropylene side chains, the oxyethylene and the oxypropylene may be located on the same or different side chains. Examples of the glucose derivative having an oxyalkylene side chain include methyl glucose caprylate/caprate, methyl glucose dioleate, methyl glucose isostearate, methyl glucose laurate, methyl glucose sesquicaprylate/sesquicaprate, methyl glucose sesquicocoate, methyl glucose sesquiisostearate, methyl glucose sesquilaurate, methyl glucose sesquioleate, methyl glucose sesquistearate, methyl glucose polyether-10, methyl glucose polyether-20, PPG-10 methyl glucose polyether (PPG-10 methyl glucose ether), PPG-20 methyl glucose ether, PPG-25 methyl glucose ether, PPG-20 methyl glucose ether acetate, PPG-20 methyl glucose ether distearate, PEG-120 methyl glucose dioleate, PEG-20 methyl glucose distearate, PEG-80 methyl glucose laurate, PEG-20 methyl glucose sesquicaprylate/sesquicaprate, PEG-20 methyl glucose sesquilaurate, PEG-20 methyl glucose sesquistearate, PEG-120 methyl glucose triisostearate, PEG-120 methyl glucose trioleate, PEG-20 methyl glucose trioleate, or PEG-12 ethyl glucose trioleate propanediol.

According to some embodiments, the glucose derivative used has a structure represented by the following formula (2).

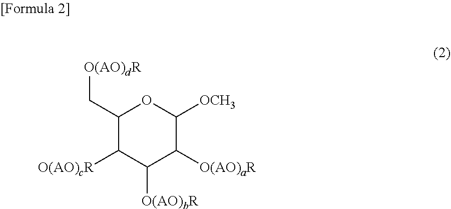

In formula (2), each AO is independently an oxyalkylene group, preferably an oxyethylene group, and/or oxypropylene group. The AO may be an oxytrimethylene group.

Each R is independently a hydrogen atom or a C1 to C18 alkyl group. According to some embodiments, each R is a C1 to C15 alkyl group, a C1 to C12 alkyl group, a C1 to C10alkyl group, a C1 to C8alkyl group, a C1 to C6 alkyl group, a C1 to C4 alkyl group, or a C1, C2, or C3 alkyl group. At least some of R may be at least one of a C2 to 21 alkenyl group, a C3 to 21 alkenyl carbonyl group, or a C2 to C21 alkyl carbonyl group.

a, b, c, and d are each independently, an integer of 1 to 150, an integer of 1 to 140, an integer of 1 to 130, an integer of 1 to 120, or an integer of 1 to 100, and preferably an integer of 1 to 50 and more preferably an integer of 1 to 30. According to some embodiments, a, b, c, and d are each independently an integer of 2 or more, an integer of 3 or more, an integer of 4 or more, an integer 5 or more, an integer 6 or more, an integer 7 or more, an integer 8 or more, an integer 9 or more, an integer 10 or more, an integer 12 or more, an integer 14 or more, an integer 16 or more, or an integer 18 or more. According to some embodiments, a, b, c, and d are each independently an integer 30 or less, an integer 28 or less, an integer 26 or less, an integer 24 or less, an integer 22 or less, an integer 20 or less, an integer 18 or less, an integer 16 or less, an integer 14 or less, or an integer 12 or less. Some of a, b, c, and d may be 0.

According to some embodiments, a+b+c+d is an integer of 2 or more, an integer of 3 or more, an integer of 4 or more, an integer 5 or more, an integer 6 or more, an integer 7 or more, an integer 8 or more, an integer 9 or more, an integer 10 or more, an integer 12 or more, an integer 14 or more, an integer 16 or more, or an integer 18 or more. According to some embodiments, a+b+c+d is an integer 30 or less, an integer 28 or less, an integer 26 or less, an integer 24 or less, an integer 22 or less, an integer 20 or less, an integer 18 or less, an integer 16 or less, an integer 14 or less, or an integer 12 or less. According to some embodiments, a+b+c+d is an integer of 6 to 14. According to some embodiments, a+b+c+d is an integer of 16 to 24.

As described above, at least one glucose derivative may be used, or at least two glucose derivatives may be used. From the standpoint of more suitably exhibiting the effect of selectively removing silicon nitride, it is preferable to use at least two glucose derivatives in combination and more preferable to use a glucose derivative at least having an alkyl chain and a glucose derivative having an oxyalkylene side chain in combination. It is also more preferable to use the glucose derivative having an alkyl chain in the combination of two or more.

According to some embodiments, the glucose derivative includes a glucose derivative at least having an alkyl chain.

According to some embodiments, the glucose derivative includes glucose derivative at least having an oxyalkylene side chain.

According to some embodiments, the glucose derivative is in the form of a mixture substantially free of glucose derivatives where R1 has a C11- or lower-, C10- or lower-, C9- or lower- or C8- or lower-alkyl group in formula (1). According to some embodiments, the mass percentage of glucose derivatives in the form of this mixture is 40% by mass or more, or 50% by mass or more relative to the total amount of the glucose derivatives.

According to some embodiments, the glucose derivatives include a glucose derivative in the form of a mixture substantially free of a glucose derivative where R1 has a C11- or higher-, C12- or higher-, C13- or higher-, C14- or higher-, or C15- or higher-alkyl group in formula (1), and a glucose derivative in the form of a mixture where R₁ is C8 to C14 in formula (1). According to some embodiments, the total mass percentage of these glucose derivatives is 60% by mass or more, 70% by mass or more, 80% by mass or more, 90% by mass or more, 95% by mass or more, or 100% by mass relative to the total amount of the glucose derivatives.

According to some embodiments, the glucose derivatives include a glucose derivative where AOs are each independently an oxyethylene group in formula (2) and a+b+c+d is an integer of 6 to 14, a glucose derivative in the form of a mixture where R1 is C8 to C14 in formula (1), and a chelating agent which is a compound represented by the following formula (3) or a salt thereof, wherein R₁ to R₅ are phosphonic acid groups or alkyl groups substituted with a phosphonic acid group, or a compound represented by the following formula (4) or a salt thereof. In the embodiments, the total mass percentage of these glucose derivatives is 60% by mass or more, 70% by mass or more, 80% by mass or more, 90% by mass or more, 95% by mass or more, or 100% by mass relative to the total amount of the glucose derivatives.

According to some embodiments, the glucose derivatives include a glucose derivative where a+b+c+d is an integer of 16 to 24 in formula (2) and a glucose derivative in the form of a mixture where R₁ is C8 to C14 in formula (1). According to some embodiments, the total mass percentage of these glucose derivatives is 60% by mass or more, 70% by mass or more, 80% by mass or more, 90% by mass or more, 95% by mass or more, or 100% by mass relative to the total amount of the glucose derivatives.

According to some embodiments, the glucose derivatives include the glucose derivative where a+b+c+d is an integer of 16 to 24 in formula (2), and the glucose derivative in the form of a mixture substantially free of a glucose derivative where R₁ has a C11- or lower-, C10- or lower-, C9- or lower- or C8- or lower-alkyl group in formula (1). According to some embodiments, the total mass percentage of these glucose derivatives is 60% by mass or more, 70% by mass or more, 80% by mass or more, 90% by mass or more, 95% by mass or more, or 100% by mass relative to the total amount of the glucose derivatives.

According to some embodiments, if the glucose derivatives include a glucose derivative having an alkyl chain (in this case, the glucose derivative does not have an oxyalkylene side chain), the amount of glucose derivative having an alkyl chain is 60% by mass or more, 70% by mass or more, 80% by mass or more, 90% by mass or more, 95% by mass or more, or 100% by mass relative to the whole amount of the glucose derivatives.

According to some embodiments, if the glucose derivatives include a glucose derivative having an oxyalkylene side chain (in this case, the glucose derivative does not have an alkyl chain), the amount of glucose derivative having an oxyalkylene side chain is 60% by mass or more, 70% by mass or more, 80% by mass or more, 90% by mass or more, 95% by mass or more, or 100% by mass relative to the whole amount of the glucose derivatives.

According to some embodiments, if the glucose derivatives include a glucose derivative having an alkyl chain and a glucose derivative having an oxyalkylene side chain, the amount of the glucose derivative having an alkyl chain and the glucose derivative having an oxyalkylene side chain is 60% by mass or more, 70% by mass or more, 80% by mass or more, 90% by mass or more, 95% by mass or more, or 100% by mass relative to the whole amount of the glucose derivatives.

The upper limit of the total content of the glucose derivative relative to the total mass of the polishing composition is preferably 10% by mass or less, more preferably 5% by mass or less, still more preferably 2% by mass or less, and most preferably 1% by mass or less. According to some embodiments, the upper limit of the total content of the glucose derivative relative to the total mass of the polishing composition is 0.8% by mass or less, 0.6% by mass or less, 0.4% by mass or less, 0.2% by mass or less, 0.1% by mass or less, 0.09% by mass or less, or 0.06% by mass or less.

The lower limit of the total content of the glucose derivative relative to the total mass of the polishing composition is preferably 0.001% by mass or more, more preferably 0.005% by mass or more, still more preferably 0.01% by mass or more, and most preferably 0.02% by mass or more. According to some embodiments, the lower limit of the total content of the glucose derivative relative to the total mass of the polishing composition is 0.03% by mass or more, 0.04% by mass or more, 0.05% by mass or more, 0.06% by mass or more, or 0.07% by mass or more.

[Chelating Agent]

According to some embodiments, the polishing composition further contains a chelating agent.

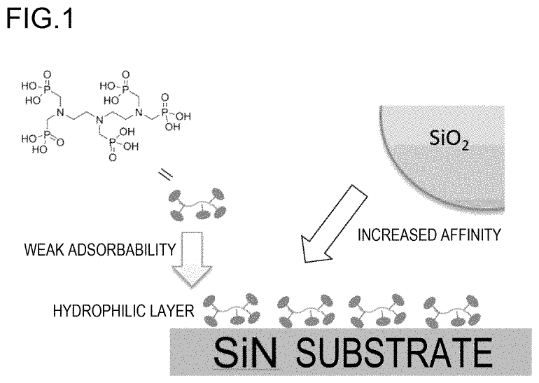

The chelating agent is usually added to the polishing composition to form a complex ion with an impurity generated by chemical mechanical polishing, thereby removing the impurity and making it possible to prevent the impurity from remaining on the surface of an object to be treated and causing contamination after polishing. However, it was found through research that a specific chelating agent can be used as a silicon nitride removal accelerator if it is used in the polishing composition of the present invention since the agent can further improve the polishing speed/removal rate of silicon nitride. It is speculated (though not limited to theory) that at least part of the reason for this is that the chelating agent contained in the polishing composition of the present invention has a weak adsorbability with the silicon nitride during polishing, forming a hydrophilic layer on the surface of the silicon nitride, and the affinity between the hydrophilic layer and colloidal silica (as shown in FIG. 1) improves the probability of contact between the silica (especially, colloidal silica) abrasive particles and the silicon nitride. Therefore, it is considered to be useful for improving the polishing speed of silicon nitride.

Examples of chelating agents that can be used in the present invention include aminocarboxylic acid chelating agents and phosphonate chelating agents.

The chelating agent that can be used in the present invention is, for example, a compound represented by the following formula (3) or a salt thereof:

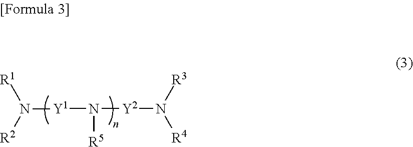

wherein Y¹ and Y² each independently represent a linear or branched alkylene group having 1 to 5 carbon atoms; n is an integer of 0 or more and 4 or less; R¹ to R⁵ are each independently a phosphonic acid group, a carboxyl group, an alkyl group substituted with a phosphonic acid group, or an alkyl group substituted with a carboxyl group.

In some embodiments, the linear or branched alkylene group having 1 to 5 carbon atoms as Y¹ and Y² in the above formula (3) is not particularly limited and includes a linear or branched alkylene group such as a methylene group, an ethylene group, a trimethylene group, a tetramethylene group, and a propylene group. Among these, a linear or branched alkylene group having 1 to 4 carbon atoms is preferable, a linear or branched alkylene group having 1 to 3 carbon atoms is more preferable, an alkylene group having 1 or 2 carbon atoms, that is, a methylene group and an ethylene group are even more preferable, and an ethylene group is particularly preferable.

In some embodiments, in the above formula (3), n represents the number of (—Y¹—N(R⁵)—) and is an integer of 0 to 4. According to some embodiments, n is an integer of 0 or more and 3 or less, an integer of 0 or more and 2 or less, or 0 or 1. Note that if n is 2 or more, n (—Y¹—N(R⁵)—) may be the same or different.

In some embodiments, two or more of R¹ to R⁴ are phosphonic acid groups or carboxyl groups, or alkyl groups substituted with a phosphonic acid group or alkyl groups substituted with a carboxyl group; three or more of R¹ to R⁴ are phosphonic acid groups or carboxyl groups, or alkyl groups substituted with a phosphonic acid group or alkyl groups substituted with a carboxyl group; or four of R¹ to R⁴ are phosphonic acid groups or carboxyl groups, or alkyl groups substituted with a phosphonic acid group or alkyl groups substituted with a carboxyl group. In some embodiments, R⁵ is a phosphonic acid group or a carboxyl group, or an alkyl group substituted with a phosphonic acid group or an alkyl group substituted with a carboxyl group. R¹ to R⁵ (or R¹ to R⁴) may be the same or different. The alkyl groups in the alkyl groups substituted with a phosphonic acid group or the alkyl groups substituted with a carboxyl group each independently have 1 to 4, 1 to 3, or 1 or 2 carbon atoms.

The chelating agent that can be used in the present invention is, for example, a compound represented by the following formula (4) or a salt thereof:

[Formula 4]

C(R⁶)(R⁷)(R⁸)(R⁹) (4)

wherein R⁶ to R⁹ are each independently a hydrogen atom, a phosphonic acid group, an alkyl group having 1 to 4 carbon atoms substituted with a phosphonic acid group, a hydroxy group, or an alkyl group having 1 to 4 carbon atoms, where at least one of R⁶ to R⁹ is a phosphonic acid group or an alkyl group having 1 to 4 carbon atoms substituted with a phosphonic acid group. Here, the alkyl groups having 1 to 4 carbon atoms (including those substituted with a phosphonic acid group) include, for example, alkyl groups such as methyl groups, ethyl groups, propyl groups, isopropyl groups, butyl groups, isobutyl groups, sec-butyl groups, and tert-butyl groups.

In some embodiments, at least two of R⁶ to R⁹ are phosphonic acid groups or alkyl groups having 1 to 4 carbon atoms substituted with a phosphonic acid group. In some embodiments, two of R⁶ to R⁹ are phosphonic acid groups or alkyl groups having 1 to 4 carbon atoms substituted with a phosphonic acid group. In some embodiments, two of R⁶ to R⁹ are phosphonic acid groups. In some embodiments, one or two of R⁶ to R⁹ are each independently a hydroxy group or an alkyl group having 1 to 4 carbon atoms. In some embodiments, one of R⁶ to R⁹ is a hydroxy group, and one of R⁶ to R⁹ is an alkyl group having 1 to 4 carbon atoms (1 to 3 carbon atoms or 1 or 2 carbon atoms).

The chelating agent that can be used in the present invention is, for example, a compound represented by the following formula (5) or a salt thereof:

[Formula 5]

N(R¹⁰)(R¹¹)(R¹²) (5)

wherein R¹⁰ to R¹² are each independently a hydrogen atom, a hydroxy group, a phosphonic acid group, a carboxyl group, an alkyl group having 1 to 4 carbon atoms substituted with a phosphonic acid group, an alkyl group having 1 to 4 carbon atoms substituted with a hydroxy group, an alkyl group having 1 to 4 carbon atoms substituted with a carboxyl group, or an alkyl group having 1 to 4 carbon atoms, where at least one of R⁶ to R⁹ is a phosphonic acid group, a carboxyl group, an alkyl group having 1 to 4 carbon atoms substituted with a phosphonic acid group, or an alkyl group having 1 to 4 carbon atoms substituted with a carboxyl group. Here, the alkyl groups having 1 to 4 carbon atoms (including those substituted with a phosphonic acid group, a carboxyl group, or a hydroxy group) include, for example, alkyl groups such as methyl groups, ethyl groups, propyl groups, isopropyl groups, butyl groups, isobutyl groups, sec-butyl groups, and tert-butyl groups.

In some embodiments, at least two of R¹⁰ to R¹² are phosphonic acid groups, carboxyl groups, alkyl groups having 1 to 4 carbon atoms substituted with a phosphonic acid group, or alkyl groups having 1 to 4 carbon atoms substituted with a carboxyl group. In some embodiments, one of R⁶ to R⁹ is an alkyl group having 1 to 4 carbon atoms substituted with a hydroxy group.

Examples of the aminocarboxylic acid chelating agents include hydroxyethyliminodiacetic acid, ethylendiaminetetraacetic acid, sodium ethylendiaminetetraacetate, nitrilotriacetic acid, sodium nitrilotriacetate, ammonium nitrilotriacetate, hydroxyethylethylenediaminetriacetic acid, sodium hydroxyethylethylenediaminetriacetate, diethylenetriaminepentaacetic acid (DTPA), sodium diethylenetriaminepentaacetate, triethylenetetraminehexaacetic acid, and sodium triethylenetetraminehexaacetate.

Examples of the phosphonate chelating agents include 2-aminoethylphosphonic acid, 1-hydroxyethylidene-1,1-diphosphonic acid, aminotris(methylenephosphonic acid), ethylenediamine tetrakis(methylene phosphonic acid), diethylenetriamine penta(methylene phosphonic acid), ethane-1,1-diphosphonic acid, ethane-1,1,2-triphosphonic acid, ethane-1-hydroxy-1,1-diphosphonic acid, ethane-1-hydroxy-1,1,2-triphosphonic acid, ethane-1,2-dicarboxy-1,2-diphosphonic acid, methanehydroxy phosphonic acid, 2-phosphonobutane-1,2-dicarboxylic acid, 1-phosphonobutane-2,3,4-tricarboxylic acid, and α-methylphosphonosuccinic acid. Among these chelating agents, hydroxyethyliminodiacetic acid, diethylenetriamine penta(methylene phosphonic acid), ethylenediamine tetrakis(methylene phosphonic acid), 1-hydroxyethylidene-1,1-diphosphonic acid, aminotris(methylenephosphonic acid), and ethylendiaminetetraacetic acid are preferred.

The chelating agent content relative to the total mass of the polishing composition is preferably 0.0001% by mass or more, more preferably 0.0005% by mass or more, and still more preferably 0.001% by mass or more, and in some embodiments, the chelating agent content relative to the total mass of the polishing composition is 0.003% by mass or more, 0.005% by mass or more, 0.007% by mass or more, 0.009% by mass or more, 0.011% by mass or more, 0.013% by mass or more, 0.015% by mass or more, 0.017% by mass or more, 0.019% by mass or more, 0.021% by mass or more, or 0.023% by mass or more. The polishing speed of silicon nitride can be increased by increasing the chelating agent content. The chelating agent content in the polishing composition is preferably 0.5% by mass or less, more preferably 0.1% by mass or less, and still more preferably 0.05% by mass or less. In some embodiments, the chelating agent content relative to the total mass of the polishing composition is 0.04% by mass or less, or 0.03% by mass or less. The storage stability of the polishing composition can be better maintained by reducing the chelating agent content.

In some embodiments, if the chelating agent includes an aminocarboxylic acid chelating agent and/or a phosphonate chelating agent, the percentage of the aminocarboxylic acid chelating agent and/or the phosphonate chelating agent in the chelating agent is 60% by mass or more, 70% by mass or more, 80% by mass or more, 90% by mass or more, 95% by mass or more, or 98% by mass or more.

[pH Regulator (pH Adjusting Agent)]

The polishing composition of the present invention includes a pH regulator. The pH of the polishing composition can be adjusted to the desired value by the pH regulator. Known acidic compounds or basic compounds can be used as pH regulators.

The acidic compounds may be inorganic acids or organic acids. Examples of the inorganic acids include hydrochloric acid (HCl), sulfuric acid (H₂SO₄), nitric acid (HNO₃), hydrofluoric acid (HF), boric acid (H₃BO₃), carbonic acid (H₂CO₃), hypophosphorous acid (H₃PO₂), phosphorous acid (H₃PO₃), and phosphoric acid (H₃PO₄). Among these inorganic acids, hydrochloric acid, sulfuric acid, nitric acid, and phosphoric acid are preferred.

Examples of the organic acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, hydroxyacetic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, glyoxylic acid, 2-furancarboxylic acid, 2,5-furandicarboxylic acid, 3-furancarboxylic acid, 2-tetrahydrofuran carboxylic acid, methoxyacetic acid, methoxyphenylacetic acid, and phenoxyacetic acid. Organic sulfuric acids such as methanesulfonic acid, ethanesulfonic acid, and isethionic acid (2-hydroxyethanesulfonic acid) may also be used. Among these organic acids, monocarboxylic acids such as acetic acid; dicarboxylic acids such as malonic acid, succinic acid, glutaric acid, adipic acid, pimelic acid, maleic acid, phthalic acid, malic acid, and tartaric acid; and tricarboxylic acids such as citric acid are preferred.

Examples of the basic compounds include hydroxides or salts of alkali metals, hydroxides or salts of group 2 elements, quaternary ammonium hydroxides or salts thereof, ammonia, and amines. Examples of the alkali metals include potassium and sodium.

The polishing composition of the present invention has a pH of less than 3. When the pH is too high (e.g., if pH is 3 or more), the removal rate of parts with relatively low heights on the surface in the same object to be treated is likely to increase, and the difference (ratio) in removal rate of parts with different heights on the surface of the same object to be treated is likely to decrease. As a result, this is disadvantageous for reducing or eliminating the step difference. The upper limit of the pH is preferably 2.8 or less, more preferably 2.6 or less, and still more preferably 2.4 or less. The upper limit of the pH may be 2.7 or less, 2.5 or less, 2.3 or less, or 2.2 or less. Note that the lower limit of the pH of the polishing composition of the present invention is not particularly limited. However, in consideration of manufacturing process safety and the burden of waste water treatment, it is preferably 0.8 or more, more preferably 1 or more, and still more preferably 1.5 or more. The lower limit of the pH may be 1.6 or more, 1.7 or more, 1.8 or more, 1.9 or more, 2.0 or more, or more than 2.0. The polishing composition of the present invention preferably has a pH within the range of 0.8 or more and less than 3. The pH in the present invention refers to pH at 25° C. The pH at 25° C. can be measured with a pH meter and is a numerical value after the electrode is immersed in the polishing composition for 1 minute.

The content of the pH regulator (pH adjusting agent) of the polishing composition of the present invention is not particularly limited and can be any content that results in the desired pH.

[Other Components]

As long as the effects of the present invention are not impaired, the polishing composition of the present invention may contain other components (components different from those specifically described above). Examples of the other components include surfactants, organic acids, organic acid salts, inorganic acids, inorganic acid salts, antiseptic agents, antifungal agents, and other well-known additives used in the polishing composition.

Examples of the surfactants include polyethylene glycol (polyoxyethylene); polypropylene glycol (poly-1,2-epoxypropane); random copolymers of oxyethylene and 1,2-epoxypropane; block copolymers of oxyethylene and 1,2-epoxypropane; polyoxyethylene alkyl ethers; and polyoxyethylene sorbitan fatty acid esters. Among them, polyethylene glycol and polypropylene glycol are particularly preferable. One or two or more of these surfactants may be used, or two or more of the same surfactants having different molecular weights may be used in a mixture. The surfactants have an average molecular weight of preferably 300 to 50,000.

According to some embodiments, the other components comprise 10% by mass or less, 5% by mass or less, 4% by mass or less, 3% by mass or less, 2% by mass or less, 1% by mass or less, 0.5% by mass or less, 0.1% by mass or less, 0.05% by mass or less, 0.001% by mass or less, or 0.0005% by mass or less relative to the components excluding a dispersing medium.

[Dispersing Medium]

The polishing composition of the present invention contains a dispersing medium (which may be referred to as a “solvent”). The dispersing medium can be used to disperse or dissolve each component in the polishing composition. In the present invention, the polishing composition may contain water as a dispersing medium. From the standpoint of inhibiting the action on other components, water containing as few impurities as possible is preferable. More specifically, pure water or ultrapure water from which foreign matter has been removed through a filter after removing impurity ions with an ion exchange resin, or distilled water is preferable.

In some embodiments, the percentage of water content in the dispersing medium is 60% by mass or more, 70% by mass or more, 80% by mass or more, 90% by mass or more, 95% by mass or more, 96% by mass or more, 97% by mass or more, 98% by mass or more, 99% by mass or more, or 100% by mass.

In some embodiments, if the polishing composition contains abrasive particles, a pH regulator, a chelating agent, at least one glucose derivative, and a dispersing medium, among the components excluding the dispersing medium, the total percentage of the abrasive particles, pH regulator, chelating agent, and at least one glucose derivative is 60% by mass or more, 70% by mass or more, 80% by mass or more, 90% by mass or more, 95% by mass or more, 96% by mass or more, 97% by mass or more, 98% by mass or more, 99% by mass or more, or 99.5% by mass or more.

[Application]

The polishing composition of the present invention is used to treat a specific object. The treatment method is not particularly limited, and for example, flattening treatment, selective removal treatment, and cleaning treatment can be performed. The treatment method is preferably chemical mechanical polishing. The polishing step may be a polishing step comprising a single step or a polishing step comprising a plurality of steps. Examples of the polishing step comprising a plurality of steps include a step in which a finish polishing step is performed after a preliminary polishing step (rough polishing step) or a step in which one or two or more secondary polishing steps are performed after a primary polishing step, followed by a finish polishing step.

[Object to be Treated]

The object to be treated using the polishing composition of the present invention is not particularly limited, and examples thereof include a semiconductor material such as a wafer and a substrate, or an optical element such as a lens and a glass substrate. The object is preferably a material or an element whose silicon nitride needs to be removed or selectively removed. The components of the object to be treated are not particularly limited, either, but preferably contain silicon nitride or polysilicon and silicon nitride, more preferably those containing polysilicon and silicon nitride.

[Surface Treatment Apparatus (Polishing Apparatus)]

The surface treatment apparatus using the polishing composition of the present invention is not particularly limited, and examples thereof include apparatus to perform flattening treatment, selective removal treatment, and cleaning treatment on an object to be treated.

As the surface treatment apparatus (polishing apparatus), it is possible to use general polishing apparatus being attached with a holder for holding a substrate or the like having an object to be polished and a motor or the like that can change the number of rotation, and having a platen to which a polishing pad (polishing cloth) can be attached.

As the polishing pad, a general nonwoven fabric, polyurethane, a porous fluororesin, or the like can be used without any particular limitation. The polishing pad is preferably grooved such that the polishing composition can be stored therein.

Polishing conditions are not particularly limited, either. For example, the rotational speed of the platen is preferably 10 to 500 rpm, the rotational speed of a carrier is preferably 10 to 500 rpm, and the pressure (polishing pressure) applied to a substrate having an object to be polished is preferably 0.1 to 10 psi. A method for supplying the polishing composition to the polishing pad is not particularly limited, either. For example, a method for continuously supplying the composition with a pump or the like is employed. This supply amount is not limited, and a surface of the polishing pad is preferably covered all the time with the polishing composition of the present invention.

[Method for Selectively Removing Silicon Nitride]

The present invention also provides a method for selectively removing silicon nitride using the above polishing composition.

The method of the present invention for selectively removing silicon nitride the present invention is not particularly limited, as long as the polishing composition is used as described in the present invention, and may be performed in conjunction with known manufacturing and treatment methods for a semiconductor material or an optical element.

In some embodiments, the selection ratio of silicon nitride/polysilicon under conditions in measurements of the polishing speed described in Examples is 10 or more, more than 14.8, 15 or more, 20 or more, more than 23.5, 25 or more, 30 or more, more than 34.9, 35 or more, 40 or more, 45 or more, 46.2 or more, 50 or more, 55 or more, 56.3 or more, or 60 or more.

### Examples

Hereinafter, the present invention will be further described by Examples and Comparative Examples, but the scope of the present invention is not limited to Examples below. Unless otherwise described in Examples below, all polishing operation conditions are room temperature (20 to 25° C.)/relative humidity 40 to 50% RH.

[Preparation of Polishing Composition]

While abrasive particles, a chelating agent, a first glucose derivative, and a second glucose derivative were mixed in a dispersing medium (ultrapure water) with compositional features shown in the following Table 1, the pH was adjusted with a pH regulator (mixing temperature: about 25° C., mixing time: about 10 minutes) to prepare a polishing composition. The pH of the polishing composition was checked by a pH meter (model number: LAQUA manufactured by HORIBA, Ltd.) (temperature of the polishing composition at pH measurement is 25° C.). “−” in Table 1 indicates that the component is not added. Each component and number in Table 1 will be described as follows. Note that as shown in Table 1, at least part of the chelating agent, the first glucose derivative, and the second glucose derivative are not included in some Examples and Comparative Examples.

SiO₂: colloidal silica of which surface is immobilized with sulfonic acid [average primary particle size: 35 nm and average secondary particle size: 70 nm],

DTPMP: diethylenetriamine penta(methylene phosphonic acid),

ATMP: aminotris(methylenephosphonic acid),

HEDP: 1-hydroxyethylidene-1,1-diphosphonic acid,

HIDA: hydroxyethyliminodiacetic acid,

EDTA: ethylendiaminetetraacetic acid,

G1-1: caprylyl/myristyl glucoside, in the following formula, n=7 to 13 in alkyl chain (R) (DP: 1 to 5),

G1-2: caprylyl/capryl glucoside, in the following formula, n=7 to 9 in alkyl chain (R) (DP: 1 to 5),

G1-3: lauryl/myristyl glucoside, in the following formula, n=11 to 13 in alkyl chain (R) (DP: 1 to 5),

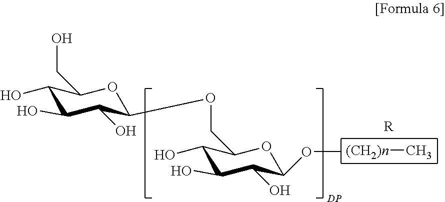

The molecular structure of APGs: R=(fatty) alkyl group, DP=average number of glycose units/alkyl chain (R) (degree of polymerization)

G1-4: glucose,

G2-1: methyl glucose polyether-10:

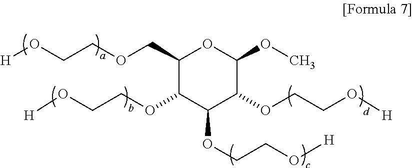

(a+b+c+d=10),
G2-2: methyl glucose polyether-20:

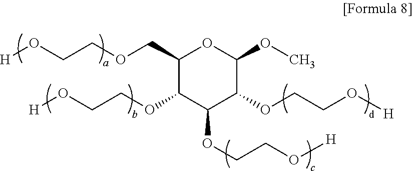

(a+b+c+d=20),

G2-3: PPG-10 methyl glucose polyether:

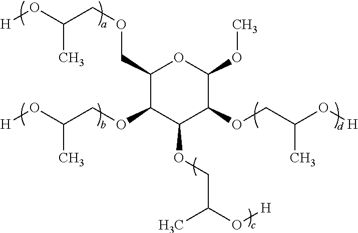

(a+b+c+d=10),

RR [Å/min]: polishing speed.

### [Measurement of Polishing Speed]

Each wafer was polished under the following conditions using the polishing composition obtained in the preparation of the polishing composition above, and the polishing speed was measured.

Polishing apparatus: FREX 300E, manufactured by EBARA Corporation

Polishing pad: IC1010, manufactured by Rohm and Haas Company

Dresser: A188, manufactured by 3M Corporation

Polishing time of silicon nitride: 60 seconds

Polishing time of polysilicon: 120 seconds

Polishing pressure: 1 psi (1 psi=6894.76 Pa)

Rotational speed of platen: 90 rpm

Rotational speed of head (carrier): 90 rpm

Supply rate of polishing composition: 300 ml/minute.

TABLE 1

| | Component of polishing composition | | | | | | | | | | | | |
|---|---|---|---|---|---|---|---|---|---|---|---|---|---|
| | | | | | | | | | Second | | | | Selection |
| | | | | | | | | | glucose | | Measurement result | | ratio |
| | Abrasive | | | | Chelating | | First glucose | | derivative/ | | Silicon | | Silicon |
| | particle/content | | pH | | agent/content | | derivative/content | | content | | nitride | polysilicon | nitride/ |
| Example | (% by mass) | | regulator | pH | (% by mass) | | (% by mass) | | (% by mass) | | RR(Å/min) | RR(Å/min) | polysilicon |
| 1 | SiO₂ | 0.5 | Nitric acid | 2.1 | DTPMP | 0.025 | G1-1 | 0.04 | — | — | 494 | 21 | 23.5 |
| 2 | SiO₂ | 0.5 | Nitric acid | 2.1 | DTPMP | 0.025 | G2-1 | 0.04 | — | — | 512 | 24 | 21.3 |
| 3 | SiO₂ | 0.5 | Nitric acid | 2.1 | DTPMP | 0.025 | G1-1 | 0.04 | G2-1 | 0.04 | 554 | 13 | 42.6 |
| 4 | SiO₂ | 0.5 | Nitric acid | 2.1 | DTPMP | 0.025 | G1-1 | 0.04 | G2-2 | 0.04 | 535 | 9 | 59.4 |
| 5 | SiO₂ | 0.5 | Nitric acid | 2.1 | DTPMP | 0.025 | G1-1 | 0.04 | G2-3 | 0.04 | 562 | 17 | 33.1 |
| 6 | SiO₂ | 0.5 | Nitric acid | 2.1 | DTPMP | 0.025 | G1-2 | 0.04 | G2-2 | 0.04 | 516 | 12 | 43.0 |
| 7 | SiO₂ | 0.5 | Nitric acid | 2.1 | DTPMP | 0.025 | G1-3 | 0.04 | G2-2 | 0.04 | 518 | 8 | 64.8 |
| 8 | SiO₂ | 0.5 | Nitric acid | 2.1 | DTPMP | 0.025 | G1-2 | 0.04 | G1-1 | 0.04 | 498 | 10 | 49.8 |
| 9 | SiO₂ | 0.5 | Nitric acid | 2.1 | DTPMP | 0.025 | G1-1 | 0.04 | G1-3 | 0.04 | 507 | 9 | 56.3 |
| 10 | SiO₂ | 0.5 | Nitric acid | 2.1 | DTPMP | 0.025 | G2-1 | 0.04 | G2-2 | 0.04 | 498 | 18 | 27.7 |
| 11 | SiO₂ | 0.5 | Nitric acid | 2.1 | DTPMP | 0.025 | G2-1 | 0.04 | G2-3 | 0.04 | 504 | 14 | 36.0 |
| 12 | SiO₂ | 0.5 | Nitric acid | 2.1 | ATMP | 0.025 | G1-1 | 0.04 | G2-1 | 0.04 | 451 | 10 | 45.1 |
| 13 | SiO₂ | 0.5 | Nitric acid | 2.1 | HEDP | 0.025 | G1-1 | 0.04 | G2-1 | 0.04 | 554 | 12 | 46.2 |
| 14 | SiO₂ | 0.5 | Nitric acid | 2.1 | HIDA | 0.025 | G1-1 | 0.04 | G2-1 | 0.04 | 445 | 11 | 40.5 |
| 15 | SiO₂ | 0.5 | Nitric acid | 2.1 | EDTA | 0.025 | G1-1 | 0.04 | G2-1 | 0.04 | 488 | 14 | 34.9 |
| | Component of polishing composition | | | | | | | | | | | | |
| | | | | | | | | | Second | | | | Selection |
| | | | | | | | | | glucose | | Measurement result | | ratio |
| | Abrasive | | | | Chelating | | First glucose | | derivative/ | | Silicon | | Silicon |
| Comparative | particle/content | | pH | | agent/content | | derivative/content | | content | | nitride | polysilicon | nitride/ |
| Example | (% by mass) | | regulator | pH | (% by mass) | | (% by mass) | | (% by mass) | | RR(Å/min) | RR(Å/min) | polysilicon |
| 1 | SiO₂ | 0.5 | Nitric acid | 2.1 | — | — | — | — | — | — | 353 | 41 | 8.6 |
| 2 | SiO₂ | 0.5 | Nitric acid | 2.1 | DTPMP | 0.025 | — | — | — | — | 492 | 52 | 9.5 |
| 3 | SiO₂ | 0.5 | Nitric acid | 2.1 | DTPMP | 0.025 | Changed to | 0.04 | — | — | 497 | 50 | 9.9 |
| | | | | | | | glucose G1-4 | | | | | | |

As shown in Table 1, compared to Comparative Examples 1 and 2, polishing using the polishing compositions of Examples 1 and 2 containing one glucose derivative decreases the polishing speed of polysilicon, and silicon nitride is polished at a higher polishing speed. In Examples 3 to 15, the use of two glucose derivatives can further enhance a protective effect of a polysilicon substrate surface. As can be seen from the experimental results, among Examples 1 to 11 using the same chelating agent, the polishing speed of polysilicon in Examples 3 to 11 is lower than in Examples 1 and 2, but the polishing speed of silicon nitride is equivalent to or higher than in Examples land 2. In addition, the polishing compositions of Examples 1 to 13 using a phosphonate chelating agent and Examples 14 and 15 using an aminocarboxylic acid chelating agent all have effects capable of efficiently and selectively removing silicon nitride for polysilicon.

As can be seen from Comparative Examples 2 and 3, the addition of the phosphonate chelating agent is useful for improving the polishing speed of silicon nitride. However, although silicon nitride can be polished at a high polishing speed, the polishing speed of polysilicon is also increased at the same time, potentially affecting the effect of selectively removing silicon nitride for polysilicon. As can be seen from Comparative Examples 2 and 3, glucose is additionally added to the polishing composition of Comparative Example 3, the polishing speed of the silicon nitride and the polishing speed of the polysilicon are almost the same as those in Comparative Examples 2, indicating that glucose does not exhibit any significant effect on the polishing composition. Compared to Examples 1 to 15 using a glucose derivative, Comparative Example 3 with glucose used is not as effective in selectively removing silicon nitride.

Note that the present application is based on Japanese Patent Application No. 2021-57279, filed on Mar. 30, 2021, the entire disclosure of which is incorporated herein by reference.

1. A polishing composition comprising abrasive particles and at least one glucose derivative, and having a pH of less than 3.

2. The polishing composition according to claim 1, comprising at least two glucose derivatives.

3. The polishing composition according to claim 1, wherein the glucose derivative has an alkyl chain.

4. The polishing composition according to claim 3, wherein the glucose derivative has an oxyalkylene side chain.

5. The polishing composition according to claim 1, wherein the abrasive particles are silica particles.

6. The polishing composition according to claim 5, wherein the silica particles are sulfonic acid-immobilized colloidal silica.

7. The polishing composition according to claim 1, further comprising a chelating agent.

8. The polishing composition according to claim 7, wherein the chelating agent comprises a phosphonate chelating agent.

9. The polishing composition according to claim 1, further comprising a pH regulator.

10. A method for selectively removing silicon nitride using the polishing composition according to claim 1.
